(19) United States
(12) Patent Application Publication
(10) Pub. No.: US 2025/0228040 A1
(43) Pub. Date: Jul. 10, 2025

(54) ULTRAHIGH EFFICIENCY EXCITONIC DEVICE

(71) Applicant: THE REGENTS OF THE UNIVERSITY OF MICHIGAN, Ann Arbor, MI (US)

(72) Inventors: Ayush PANDEY, Ann Arbor, MI (US); Jungwook MIN, Ann Arbor, MI (US); Yakshita MALHOTRA, Ann Arbor, MI (US); Maddaka REDDEPPA, Ann Arbor, MI (US); Yixin XIAO, Ann Arbor, MI (US); Zetian MI, Ann Arbor, MI (US)

(21) Appl. No.: 19/094,735

(22) Filed: Mar. 28, 2025

Related U.S. Application Data
(63) Continuation of application No. PCT/US2023/034204, filed on Sep. 29, 2023.
(60) Provisional application No. 63/411,969, filed on Sep. 30, 2022.

(51) Int. Cl. H10H 20/812; H10H 20/819; H10H 20/825

(52) U.S. Cl. CPC H10H 20/812; H10H 20/819; H10H 20/8252

(57) ABSTRACT

An excitonic device includes a substrate and nanowires coupled to the substrate. Electrons and holes are spatially confined within an active region of each nanowire. The nanowires are operable for electroluminescent emission originating from excitons comprising bound states of electrons and holes in the active region of each nanowire.

### RELATED U.S. APPLICATION

This application is a continuation application of PCT Application No. PCT/US2023/034204, filed Sep. 29, 2023, which claims priority to the U.S. Provisional Application No. 63/411,969, filed Sep. 30, 2022, both of which are hereby incorporated by reference in their entirety.

### BACKGROUND

Since 1962, visible semiconductor light-emitting diodes (LEDs) have been widely used in our daily lives, ranging from displays, mobile phones, and lighting to emerging technologies like virtual/augmented reality. The device efficiency (e.g., external quantum efficiency (EQE)) has been dramatically improved over the past decades, reaching over 80% for gallium-nitride (GaN)-based blue LEDs. Similarly, high efficiency red LEDs can be realized utilizing aluminum-gallium-indium-phosphorous (AlGaInP)-based materials. To date, however, these devices have relatively large dimensions, generally on the millimeter scale. For future virtual/augmented reality displays, much smaller visible LEDs are required. However, the efficiency of conventional microscale and nanoscale quantum well LEDs is reduced to negligibly small values when scaled down to such dimensions.

FIG. 1 shows the EQE for some previously reported InGaN-based green and red LEDs with different sizes of active region areas, showing a significant reduction in device efficiency with decreasing sizes. The EQE of smaller-sized InGaN-based devices is often one to two orders of magnitude lower than that of conventional broad-area LEDs, especially for devices operating in the green and red spectra.

The underlying challenges to improving device efficiency have been extensively studied, including the effects of etch-induced damage, degraded p-type contact, and significantly enhanced nonradiative surface recombination. Various approaches have been employed to enhance the efficiency of microscale and nanoscale quantum well LEDs but with very limited success.

The efficiency of an LED is fundamentally limited by Shockley-Read-Hall recombination, Auger recombination, and electron overflow/leakage. While Auger recombination and electron overflow are often manifested as efficiency droop at relatively high current densities, Shockley-Read-Hall recombination severely limits the quantum efficiency at low injection currents. In this regard, the significantly enhanced surface recombination of microscale and nanoscale LEDs sets a fundamental limitation for conventional quantum well structures.

### SUMMARY

An exciton—a bound state of an electron and hole through strong Coulomb interaction—can drastically enhance the radiative recombination efficiency, which can be potentially exploited to make microscale and nanoscale LEDs relatively immune from the presence of defects/traps. However, in conventional c-plane InGaN quantum well structures, the large spontaneous and strain-induced piezoelectric polarization fields and the resulting quantum-confined Stark effect (QCSE) significantly weaken the exciton binding energy, preventing the exploitation of the excitonic effect to overcome the efficiency bottleneck of micro-LEDs (e.g., visible LEDs with lateral dimensions as small as one micrometer).

As disclosed herein, the exciton binding energy of GaN-based quantum well heterostructures is significantly enhanced through quantum and nanoscale engineering. For example, compared to conventional quantum wells, the exciton oscillator strength is enhanced by nearly two orders of magnitude in small-size (small diameter) InGaN nanowires, due to efficient strain relaxation. Further, structures grown along semi-polar planes as disclosed herein have a larger exciton binding energy due to reduced polarization fields, for example, and therefore have enhanced electron-hole wavefunction overlap.

Disclosed herein are high-efficiency, submicron-scale devices (e.g., LEDs) with lateral dimensions as small as 100 nanometers (or 0.1 microns/micrometers), which is a surface area that is orders of magnitude smaller than conventional broad-area devices. As mentioned above, the efficiency of conventional quantum well LEDs is reduced to negligibly small values when scaled down to such small dimensions. Also disclosed herein are nanowire excitonic devices with significantly enhanced exciton oscillator strength of InGaN quantum disks that overcome that fundamental challenge. Such nanowire excitonic devices can be used for the next generation of mobile displays, virtual/augmented reality, and ultrahigh speed optical interconnect, for example.

In an embodiment, an excitonic device includes a substrate and nanowires coupled to the substrate. Electrons and holes are spatially confined within an active region of each nanowire. The nanowires are operable for electroluminescent emission originating from excitons comprising bound states of electrons and holes in the active region of each nanowire. The active region of each nanowire includes layers of a semiconductor material on respective semi-polar planes and respective c-planes within the active region. The active region of each nanowire is non-uniformly doped with indium, resulting in indium-rich cluster that enhance the binding energy of the exciton.

In an embodiment, a nanowire includes a submicron-scale heterostructure, which includes: a first semiconductor region; a second semiconductor region; and an active region that includes multiple quantum disks. The quantum disks are disposed on c-planes and semi-polar planes in the active region of the nanowire, and electrons and holes are spatially confined within the active region. The nanowire is operable for excitonic electroluminescent emission originating from excitons comprising bound states of electrons and holes in the active region. The quantum disks include indium-doped quantum disks that are non-uniformly doped with indium, resulting in indium-rich clusters in the indium-doped quantum disks that enhance the binding energy of the exciton.

In an embodiment, an excitonic device includes an excitonic LED that includes submicron-scale nanowires. Each submicron-scale nanowire is operable for electroluminescent emission originating from bound states of an exciton comprising electrons and holes spatially confined in an active region of each submicron-scale nanowire. The active region of each submicron-scale nanowire is non-uniformly doped with indium, resulting in indium-rich clusters in the active region that enhance the binding energy of the exciton.

In an embodiment, an excitonic device includes a submicron inorganic crystalline semiconductor. Electrons and holes are spatially confined within an active region of each submicron inorganic crystalline semiconductor. The submicron inorganic crystalline semiconductor is operable for electroluminescent emission originating from excitons comprising bound states of electrons and holes in the active region of each submicron inorganic crystalline semiconductor. In an embodiment, the submicron inorganic crystalline semiconductor material is InGaN.

Also disclosed are several critical factors for achieving high efficiency excitonic devices (e.g., LEDs), including the epitaxy of small-size nanostructures to achieve strain relaxation, the utilization of semi-polar planes to reduce the quantum-Confined Stark effect, and the formation of nanoscale quantum-confinement to enhance electron-hole wavefunction overlap.

Embodiments disclosed herein bring excitons to the forefront in the search for mechanisms that overcome the efficiency bottleneck of not only micro-LEDs but a broad range of nanoscale optoelectronic devices including lasers, detectors, and modulators. These and other objects and advantages of embodiments according to the present invention will be recognized by one skilled in the art after having read the following detailed description, which are illustrated in the various drawing figures.

### BRIEF DESCRIPTION OF THE DRAWINGS

The accompanying drawings, which are incorporated in and form a part of this specification and in which like numerals depict like elements, illustrate embodiments of the present disclosure and, together with the detailed description, explain the principles of the disclosure. The drawings are not necessarily to scale.

FIG. 1 shows external quantum efficiency (EQE) for conventional InGaN-based green and red LEDs with different active region areas.

FIG. 2(a) shows a submicron-scale device in embodiments according to the present invention.

FIG. 2(b) shows a scanning electron microscope image of an embodiment of a nanowire array, with submicron-scale nanowires, in an embodiment according to the present invention.

FIG. 2(c) illustrates an example of the photoluminescence spectrum from a representative nanowire array, with submicron-scale nanowires, in an embodiment according to the present invention.

FIG. 3(a) shows scanning transmission electron microscopy (STEM) images of an array of submicron-scale nanowires in embodiments according to the present invention.

FIGS. 3(b) and 3(c) show high resolution images of the active (quantum disk) region near the center and edge (sidewalls), respectively, of a submicron-scale nanowire in an embodiment according to the present invention.

FIG. 3(d) shows an electron energy loss spectroscopy spectrum for the active region of a submicron-scale nanowire in embodiments according to the present invention.

FIG. 3(e) shows the indium composition measured axially at different positions along the radius of the submicron-scale nanowire of FIG. 3(d) in embodiments according to the present invention.

FIGS. 3(f) and 3(g) show STEM images of another array of submicron-scale nanowires in embodiments according to the present invention.

FIG. 4(a) shows the current density-voltage (J-V) characteristics of different devices with nanowires of different diameters, including submicron-scale nanowires, in embodiments according to the present invention.

FIG. 4(b) shows the light-current curves for different devices with nanowires of different diameters, including submicron-scale nanowires, in embodiments according to the present invention.

FIG. 4(c) shows EQE for different devices with nanowires of different diameters, including submicron-scale nanowires, in embodiments according to the present invention.

FIG. 4(d) shows the wall-plug efficiencies of different devices with nanowires of different diameters, including submicron-scale nanowires, in embodiments according to the present invention.

FIGS. 5(a) and 5(d) show the electroluminescence (EL) spectra for different devices with nanowires of different diameters, including submicron-scale nanowires, under various injection currents in embodiments according to the present invention.

FIGS. 5(b) and 5(c) are plots of the relative EQE and the individual contributions of the lower energy emission and higher energy emission measured from the EL spectra for different devices with nanowires of different diameters, including submicron-scale nanowires, in embodiments according to the present invention.

FIGS. 6(a), 6(b), 6(c), 6(d), 6(e), and 6(f) illustrate a process for fabricating submicron-scale devices in embodiments according to the present invention.

### DETAILED DESCRIPTION

Reference will now be made in detail to the various embodiments of the present disclosure, examples of which are illustrated in the accompanying drawings. While described in conjunction with those embodiments, it will be understood that they are not intended to limit the disclosure to those embodiments. On the contrary, the disclosure is intended to cover alternatives, modifications, and equivalents, which may be included within the spirit and scope of the disclosure as defined by the appended claims. Furthermore, in the following detailed description, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure.

The figures are not necessarily drawn to scale, and only portions of the devices and structures depicted, as well as the various layers that form those structures, are shown. For simplicity of discussion and illustration, only one or two devices or structures may be described, although in actuality more than one or two devices or structures may be present or formed. Also, while certain elements, components, and layers are discussed, embodiments according to the invention are not limited to those elements, components, and layers. For example, there may be other elements, components, layers, and the like in addition to those discussed.

Disclosed herein are sub-micron nanowire excitonic devices (e.g., LEDs) with InGaN quantum disks that have significantly enhanced exciton oscillator strength that improves device efficiency (e.g., EQE). Such devices overcome a fundamental problem with conventional devices that exhibit a significant reduction in device efficiency when their size (e.g., diameter) is reduced.

By exploiting the significantly enhanced exciton oscillator strength of InGaN quantum disks, submicron-scale nanowire excitonic devices (e.g., with a diameter of less than 200 nm, a diameter of 165 nm, a diameter of less than 150 nm, a diameter of 125 nm, or a diameter as small as 100 nm) with an EQE of, for example, 25.2% (which is significantly higher than that of conventional devices) are realized as disclosed herein. The excitonic submicron-scale devices disclosed herein also exhibit a wall-plug efficiency of, for example, 20.7%, which is currently a world record for micro-LEDs.

Several critical factors for achieving high-efficiency excitonic devices, including the epitaxy of small-size nanostructures to achieve strain relaxation, the utilization of semi-polar planes to reduce quantum-Confined Stark effect, and the formation of nanoscale quantum-confinement to enhance electron-hole wavefunction overlap, are also disclosed.

In embodiments disclosed herein, InGaN/GaN nanowire LED heterostructures are grown on N-polar substrates utilizing the technique of selective area epitaxy (SAE), performed in a molecular beam epitaxy (MBE) system. On a single substrate, arrays of nanowires with different dimensions and spacing are arrayed.

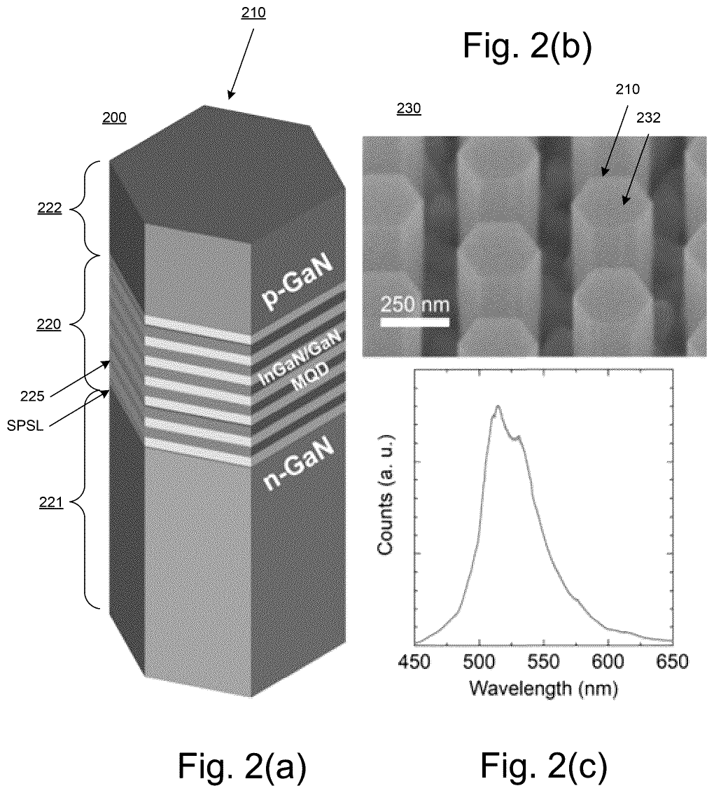

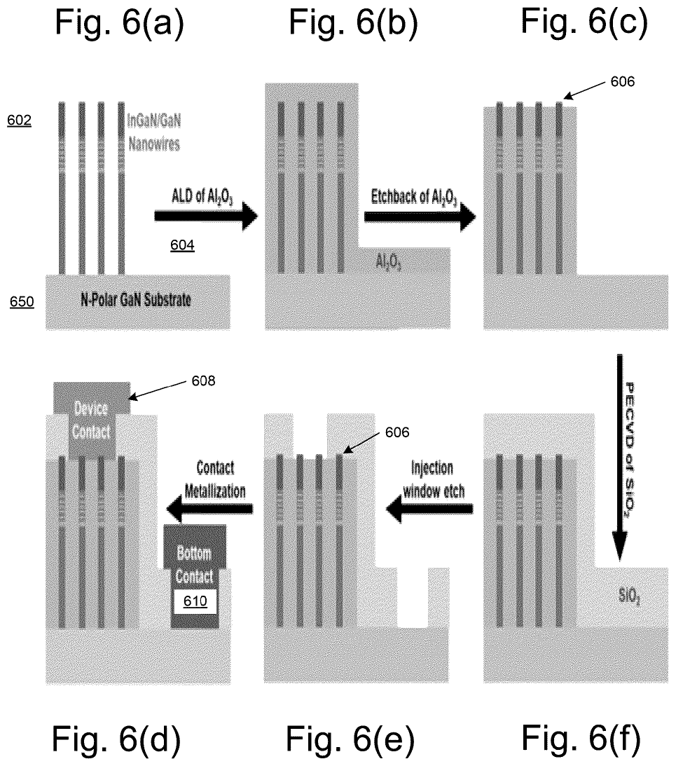

FIG. 2(a) shows a device 200 in embodiments according to the present invention. In an embodiment, the device 200 includes a nanowire 210 coupled to a substrate (e.g., the substrate 650 of FIG. 6(a)). Any practical number of such nanowires may be patterned in an array 230 on the substrate 650, as shown in FIG. 2(b). In an embodiment, the substrate 650 is an N-polar substrate, and the structure 210 is a GaN-based nanowire disposed on the substrate.

In embodiments, the nanowire 210 has a diameter of less than 200 nm. In some embodiments, the nanowire 210 has a diameter of less than 150 nm. In some embodiments, the nanowire 210 has a diameter as small as 100 nm.

FIG. 2(b) shows a scanning electron microscope (SEM) image of an embodiment of the nanowire array 230 in an embodiment according to the present invention. The structures (nanowires) in the array 230 follow the epitaxy of the substrate and are N-polar.

Each structure (nanowire) 210 in the array 230 has a “top” surface 232 that is flat around the center or centrally located region (about the longitudinal axis of the nanowire) of the nanowire and tapered around its edges. That is, the distal surface of each nanowire (the surface situated away from the “bottom” surface that is closest to the substrate 650) is flat with chamfered edges. The flat surface 232 makes the structure 210 well-suited for the fabrication of high-efficiency devices, compared to the more tapered morphology for conventional Ga-polar nanowires.

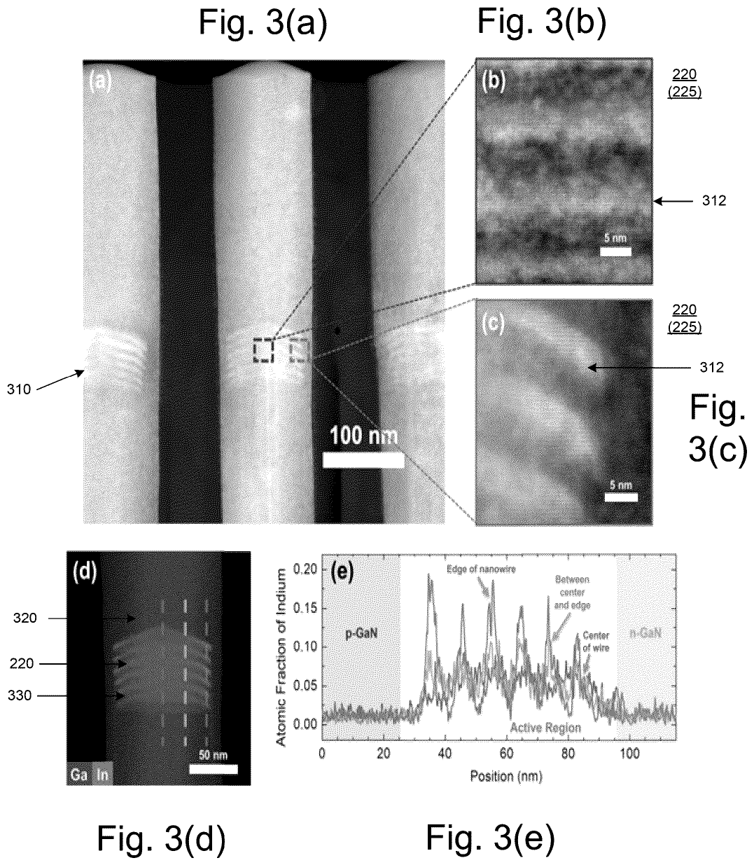

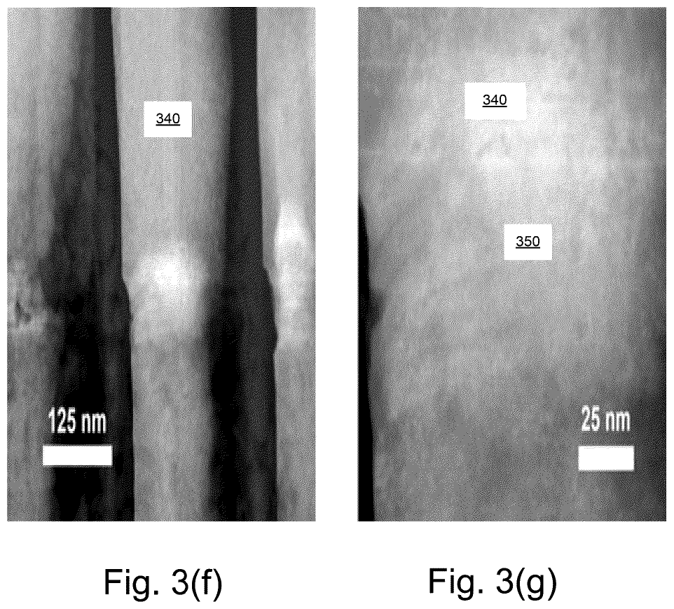

The structure 210 (FIG. 2(a)) includes a spatially confined active region 220. That is, electrons and holes are spatially confined within the active region 220. In an embodiment, the active region 220 includes layers that are disposed on semi-polar planes and c-planes within the structure 210. More specifically, the active region 220 includes layers of different semiconductor material (e.g., layers of GaN and layers of InGaN) on c-planes in the active region and semi-polar planes in the active region that intersect those c-planes. This is described further below in the discussion of FIGS. 3(b) and 3(c).

The structure 210 (FIG. 2(a)) is operable for excitonic electroluminescent emission (e.g., when electricity is supplied through electrodes coupled to the structure), where the emission originates from a bound state of electrons and holes confined within the active region 220. Specifically, in embodiments, the emission originates from a bound state of electrons and holes confined within the indium-doped (e.g., InGaN) layers in the active region 220. Significantly, the emission can occur at room temperature. Specifically, in embodiments, the exciton binding energy of the electrons and holes within the semiconductor (e.g., within the active region) is greater than 0.025 electron-volts (eV; 25 milli-electron volts), such that the excitons are bound at room temperature. 25 meV (milli-electron volts) is a critical energy because it is the thermal energy of electrons at room temperature (kT), so when the exciton binding energy becomes greater than 25 meV, the exciton binding energy is not overcome by thermal energy at room temperature, and the electron-hole pairs find a lower energy state in the bound excitonic state. The electron-hole pairs can then emit light from this slightly lower energy excitonic state, and the light has the characteristic properties of the excitonic state (e.g., energy, wavelength, lifetime).

In an embodiment, the structure (e.g., nanowire) 210 includes a submicron-scale heterostructure. The heterostructure includes a first semiconductor region 221, a second semiconductor region 222, and multiple quantum disks (MQD) 225 in the active region 220 between the first and second semiconductor regions. The quantum disks 225 are disposed on c-planes and semi-polar planes of the structure 210 as described further below. In an embodiment, the first semiconductor region 221 includes n-doped gallium nitride (n-GaN), and the second semiconductor region 222 includes p-doped gallium nitride (p-GaN).

In an embodiment, the active region 220 includes doped regions (e.g., layers doped with indium). In such an embodiment, the quantum disks 225 in the active region 220 include layers of GaN and layers of InGaN. In an embodiment, the quantum disks 225 include six pairs of InGaN/GaN quantum disks. That is, the quantum disks 225 include six InGaN layers interleaved with six GaN layers in alternating fashion.

In embodiments, the InGaN layers in the active region 220 are non-uniformly doped with indium, resulting in indium-rich clusters in those layers. In embodiments, the electroluminescent emission comes from the excitonic state originating from a bound state of electrons and holes confined in the InGaN layers of the active region 220. As described further below, the indium-rich clusters in the InGaN layers of the active region 220 enhance the binding energy of the excitons.

In an embodiment, the first semiconductor region 221 is a layer that is approximately 500 nanometers (nm) thick and is composed of silicon (Si)-doped n-GaN. In an embodiment, the second semiconductor region 222 is a layer that is approximately 230 nm thick and is composed of magnesium (Mg)-doped p-GaN.

In embodiments, a strain relaxation structure (e.g., a short-period super lattice (SPSL)) is disposed above the first semiconductor region 221 (FIG. 2(a)), between that region and the quantum disks 225. The general location of the SPSL, if included in the structure (nanowire) 210, is shown in FIG. 2(a). The SPSL is considered beneficial for the growth of the active region 220 above the strain relaxation structure; more specifically, it is beneficial for reducing strain and dislocations in the active region. In an embodiment, the SPSL is composed of alternating, relatively thin (e.g., eight nm) N-polar InGaN and N-polar GaN layers.

FIG. 2(c) illustrates an example of the photoluminescence (PL) spectrum from a representative nanowire array (e.g., the array 230 of FIG. 2(b)) in an embodiment according to the present invention. The emission includes an emission peak located at a wavelength in the green spectrum. Specifically, in the example of FIG. 2(c), the emission spectrum includes an emission peak located at a wavelength of approximately 515 nm.

The PL spectrum in the example of FIG. 2(c) is relatively broad, due to variation in the indium composition of the quantum disks 225 (FIG. 2(a)), described further below. The presence of shoulders from Fabry-Perot modes formed with the substrate 650 (FIG. 6(a)) may also be present.

The microstructures and microchemistry of the InGaN/GaN nanowire arrays disclosed herein were studied by scanning transmission electron microscopy (STEM) and x-ray energy dispersive (EDS) element mapping as described further below. STEM studies were performed on two nanowire arrays with different dimensions, referred to herein as Array A and Array B, respectively. Array A consists of nanowires with smaller diameters of approximately 125 nm and a lattice constant of 245 nm, and Array B consists of nanowires with larger diameters of approximately 165 nm and the same lattice constant.

FIG. 3(a) shows STEM images of nanowires from Array A in embodiments according to the present invention. STEM images for Array B are shown in FIGS. 3(f) and 3(g).

The region 310 in the images of FIG. 3(a) correspond to the InGaN/GaN active region 220 of FIG. 2(a). The relatively brighter areas in the region 310 correspond to the InGaN layers (e.g., InGaN layer 312). No cracks or misfit dislocations are observed, indicating the growth of a high quality InGaN/GaN active region.

FIGS. 3(b) and 3(c) show high-resolution images of the active region 220 (quantum disks 225) near the center and edge (sidewalls), respectively, of a nanowire from Array A (e.g., the nanowire 210 of FIG. 2(a)). The regions close to the nanowire surface (the edges at the circumference of the nanowire) show growth along facets (the semi-polar planes). This effect is noticeably stronger for smaller-size (smaller diameter) nanowires such as those in Array A.

In embodiments, the center region of each InGaN 312 layer in the active region 220 is disposed or incorporated on a c-plane in the active region while the edges of each InGaN layer 312 are disposed or incorporated on semi-polar planes in the active region that intersect the c-plane. The relative flat center regions of the InGaN layers, disposed on respective c-planes, are shown in FIG. 3(b). The edges of the InGaN layers, disposed on respective semi-polar planes, are shown in FIG. 3(c).

FIG. 3 (d) shows an electron energy loss spectroscopy (EELS) spectrum for the active region 220 of a nanowire 320 from Array A (e.g., the nanowire 210 of FIG. 2(a)) in embodiments according to the present invention. The relatively brighter regions 330 in FIG. 3(d) illustrate the distribution of indium in the active region 220.

FIG. 3(e) shows the indium composition measured axially at different positions along the radius of the nanowire 320 in embodiments according to the present invention (e.g., along the edge of the nanowire, between the center and edge of the nanowire, and at the center of the nanowire). FIG. 3(e) shows the atomic fraction of indium plotted along the growth direction in different regions of the nanowire 320, indicated by the dashed lines in FIG. 3(d) that correspond to the region at the edge of the nanowire, the region between the center and edge of the nanowire, and at the region at the center of the nanowire, respectively (from right to left in FIG. 3(d)).

As shown in FIG. 3(e), there is a significant increase in indium concentration (atomic fraction) in the regions closest to the nanowire sidewalls (outer edges, at the circumference of the nanowires) where the faceting is most pronounced. That is, the indium concentration at the edges of the nanowire is higher relative to the interior region of the nanowire. Indium incorporation is energetically more favored on the faceting (semi-polar planes) compared to the c-plane (see FIGS. 3(b) and 3(c)). The active region 220 (FIG. 3(d)) shows significant diffusion of indium between the wells and barriers of the quantum disks in the active region; however, the region that is close to the sidewalls maintains a high indium composition and well-defined disks and barriers, with the presence of indium-rich clusters. The indium composition also increases along the growth direction (from the center to the edge), due to the composition pulling effect.

FIGS. 3(f) and 3(g) show STEM images of Array B in embodiments according to the present invention. The STEM images of the nanowires 340 in Array B show the presence of facets, like the nanowires in Array A. However, the extent of faceting is noticeably less, with a clearer c-plane plateau visible in the center region 350 of the nanowires.

Devices fabricated on Array A and Array B are referred to herein as Device A and Device B, respectively. The injection windows of both types of devices are approximately 750 nm×750 nm in area.

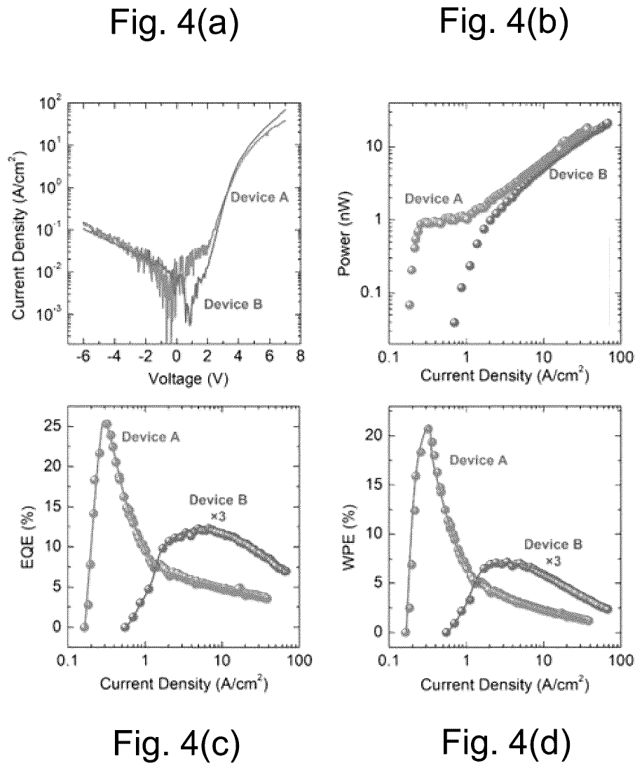

FIG. 4(a) shows the current density-voltage (J-V) characteristics of Device A and Device B in embodiments according to the present invention. These fabricated devices show rectifying characteristics with negligible reverse bias leakage, indicating the formation of well-defined p-n junctions. The current density at similar voltages is higher for Device B relative to Device A, likely due to the presence of larger densities of defects for nanowires with larger diameters; that is, the current density is lower for Device A relative to Device B likely due to the smaller densities of defects for nanowires with smaller diameters.

FIG. 4(b) shows the light-current (L-I) curves of Device A and Device B in embodiments according to the present invention. The higher current density for Device B results in that device starting to show optical emission at higher current densities than Device A as seen in FIG. 4(b). Further, two distinct regimes are present in the L-I curve for Device A: there is an initial sharp increase in power with current, followed by a saturation, and then by another more gradual increase. This phenomenon is not visible in Device B, suggesting that the nature of radiative recombination is inherently different for both devices in the different current injection regimes.

FIG. 4(c) shows the external quantum efficiencies (EQE) of Device A (smaller diameter nanowires) and Device B (larger diameter nanowires) in embodiments according to the present invention. Device B shows an EQE curve with a gradual increase up to a maximum value of approximately 4.1% at a current density of approximately five amperes per square centimeter (A/cm²). Device A, however, exhibits a significantly different trend. The EQE of Device A shows a much sharper increase in efficiency at low injection currents, reaching a maximum value of 25.2% at 0.3 A/cm², believed to be the highest value reported to date for micron scale LEDs. In general, the EQE of devices with smaller (submicron) diameters such as Device A is at least 20% is at greater than 0.1 A/cm².

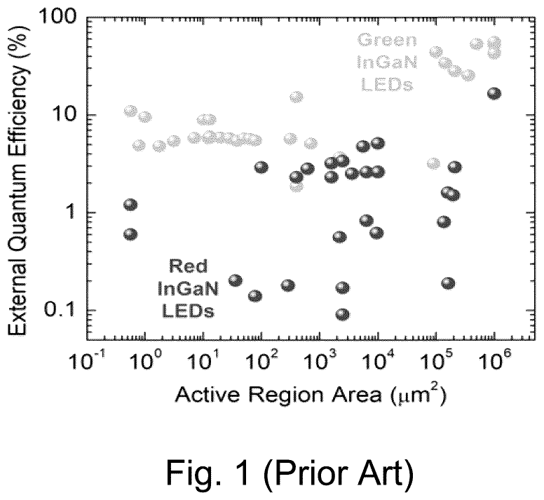

FIG. 4(d) shows the wall-plug efficiencies (WPE) of Device A (smaller diameter nanowires) and Device B (larger diameter nanowires) in embodiments according to the present invention. Shown in FIG. 4(d), a maximum WPE of 20.7% was measured for Device A. The measured EQE of 25.2% and WPE of 20.7% are significantly higher than conventional quantum well micro-LEDs of similar dimensions, shown in prior art FIG. 1. In general, the WPE of devices with smaller (submicron) diameters such as Device A is greater than 15%. The high WPE also suggests excellent carrier conduction in Device A, attributed to the efficient injection of holes into the active region of the device.

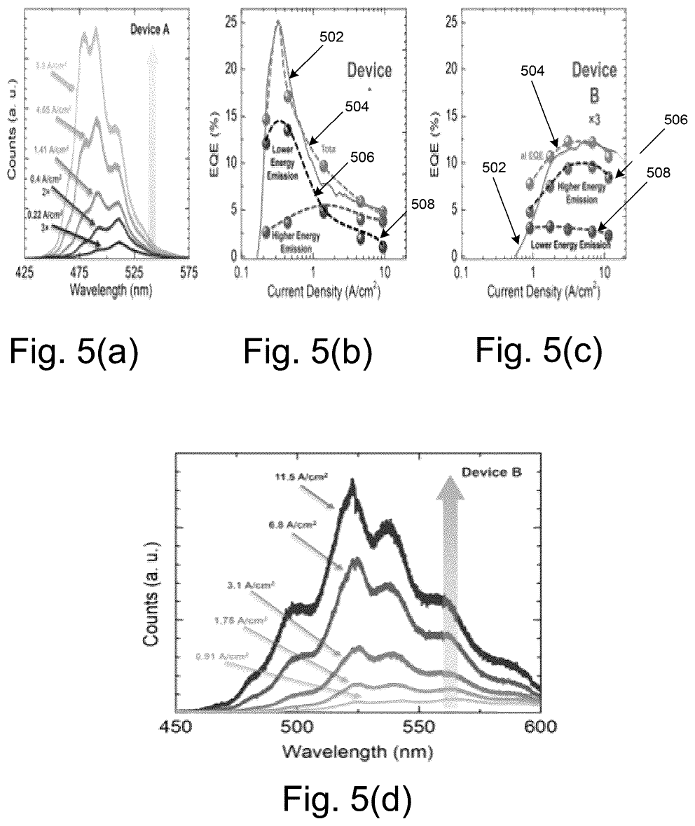

FIG. 5(a) shows the electroluminescence (EL) spectra for Device A measured under various injection currents in embodiments according to the present invention. The EL spectra for Device B are shown in FIG. 5(d). The emission from both types of devices shows Fabry-Perot modes due to the small surface roughness of the substrate.

The STEM images (FIGS. 3(a) and 3(e)) for Array A show that the nanowires have a complex distribution of indium within the quantum disks. There is significant growth of the quantum disks along the facets (semi-polar planes) near the surface (sidewalls) of the nanowires, particularly for the (smaller diameter) nanowires in Array A.

The facets are formed along the semi-polar planes due to a relatively low growth temperature. Growth temperature generally has a strong effect on the angle at which the facets are formed, due to the differing adatom mobility at different temperatures. Further, Array B, which has a larger nanowire diameter, shows reduced faceting with a more pronounced plateau on the top of the active region. As the nanowires in Array B have a larger diameter and smaller spacing between the nanowires, there will be a lower effective Ga adatom flux at the growth front due to the shadowing effect from nearby nanowires. The effectively reduced Ga flux limits the growth along the sidewalls of the nanowires and restricts the formation of facets for Array B. This explains the stronger faceting effect observed in nanowires in Array A, compared to those in Array B.

The significantly reduced polarization field along the facets (semi-polar planes) in the active region of small-size nanowires (e.g., Array A) will suppress the quantum-confined Stark effect (QCSE), thereby dramatically enhancing the excitonic binding energy for quantum disks formed on these facet layers (e.g., on the semi-polar planes), as compared to conventional c-plane InGaN quantum wells.

There is enhanced dopant (e.g., indium) incorporation in the active region near the nanowire sidewalls that, together with the higher indium composition in the near-surface faceted region, suggests that EL emission from such nanowire micro-LEDs will likely originate from that region. The stronger charge carrier confinement in the quantum disks, specifically in the indium-doped layers in the quantum disks, together with the significantly reduced strain distribution and piezoelectric polarization field, greatly enhance the electron-hole wavefunction overlap, and thereby enhance the exciton binding energy. Further, this effect depends strongly on the dimension and size of the nanostructures, with more efficient strain relaxation in structures having smaller dimensions (e.g., the submicron-scale devices of Array A). A nearly two orders of magnitude enhancement of excitonic oscillator strength is observed in small-size (submicron-scale) InGaN nanowires (e.g., with a diameter of less than 200 nm, a diameter of less than 150 nm, or a diameter as small as 100 nm), compared to conventional planar quantum wells.

In a submicron-scale excitonic LED as disclosed herein, EL emission originates from the bound state of electrons and holes, instead of recombination from free charge carriers. Due to the strong Coulombic interaction between electrons and holes, the negative impact of Shockley-Read-Hall recombination on the performance of a submicron-scale excitonic LED is significantly reduced. The EQE and device output power show a much faster rising trend with injection current for a submicron-scale excitonic LED, thereby leading to high efficiency that was not previously possible for conventional InGaN quantum well micro-LEDs. The indium-rich clusters in the faceted region of the quantum disks in the active region of the submicron-scale nanowires of Device A dominate emission at low injection currents, due to their higher indium compositions and proximity to the highly doped nanowire sidewalls. This emission shows a strong dependence on the extent of faceting and the composition of the InGaN quantum disks. This result is clearly observed in FIGS. 4(b), 4(c), and 4(d).

Device A, consisting of nanowires with smaller (submicron-scale) diameters, shows a strong excitonic effect, resulting in an EQE of at least 20% at greater than 0.1 A/cm². In an embodiment, the result is an ultrahigh peak EQE of 25.2%. Such a distinct phenomenon has not been previously seen in conventional c-plane quantum well LEDs, due to the weak excitonic effect limited by the strong QCSE in such conventional devices, as well as the high plasma damage involved in mesa etching in such conventional devices, which obscures the excitonic effect at low injection currents.

At high injection currents, the indium-rich clusters become saturated and the bulk of the diffuse c-plane InGaN (e.g., free electron-hole recombination, instead of excitons) contributes to the emission. The transition from excitonic emission to band-to-band recombination results in similar performance for nanowires with different dimensions (e.g., Devices A and B). This is indeed the case, as shown in FIGS. 4(b), 4(c), and 4(d) at relatively high current densities.

From the EL spectra in FIG. 5(a), at low injection currents corresponding to the peak EQE, the emission is dominated by the lower energy peak located in the green spectrum (e.g., at a wavelength of approximately 515 nm), which is related to the excitonic emission of the indium-rich clusters in the semi-polar quantum disks in the active region 220 (FIG. 2(a)). At higher injection currents, emission from the indium-rich clusters becomes saturated, causing the band-to-band recombination from the center region of the nanowire (c-plane quantum disks) to dominate. Indeed, as the injection current increases, the contribution of the higher energy emission at approximately 475-490 nm starts increasing relative to the low energy emission and eventually becomes the dominant emission peak. For Device B, a transition of the EL emission peak energy above the maximum EQE of 4.1% is not observed. This correlates well with the prevalence of free electron-hole recombination of Device B. A careful comparison between the EQE curves for Devices A and B shows that they become almost identical for injection currents above a few A/cm² because, at those levels, regime band-to-band recombination dominates for both types of devices.

The contribution of excitonic emission and band-to-band recombination (originating from the semi-polar and c-plane quantum disks, respectively) to the overall EQE was analyzed. FIG. 5(b) plots the relative EQE for the peak located at approximately 515 nm (lower energy emission peak) and at approximately 490 nm (higher energy emission peak) for Device A in embodiments according to the present invention. The same types of plots are shown in FIG. 5(c) for Device B. The relative EQE for the total emission from these peaks (shown by the curves 504 for each type of device) correlates closely with the actual measured EQE (shown by the curves 502 for each type of device). The higher energy emissions (curves 506 in FIGS. 5(b) and (c)) exhibit remarkably similar trends for Devices A and B, which are both peaked at a few A/cm². This EQE trend is explained by the prevalence of band-to-band recombination, together with Shockley-Read-Hall recombination and electron overflow.

However, the contribution of lower energy emissions (curves 508 in FIGS. 5 (b) and (c)) is fundamentally different between Devices A and B. Device A, having a smaller diameter, more efficient strain relaxation, more faceting, and reduced polarization fields, shows that the low energy (excitonic) emission is significantly stronger than the higher energy (band-to-band) emission in the low current regime, thereby contributing to an ultrahigh efficiency that was not previously possible for micro-LEDs. In contrast, for Device B, the low energy emission remained negligible throughout the measured current range, due to the lack of significant excitonic effect. This further provides unambiguous evidence that the significantly enhanced efficiency of Device A is not due to variations of light extraction efficiency, but rather the excitonic emission originated from the strain-relaxed quantum disks formed in dislocation-free submicron-scale nanowire arrays (e.g., with a diameter of less than 200 nm, a diameter of less than 150 nm, or a diameter as small as 100 nm).

Thus, the efficiency bottleneck of micro-LEDs is addressed by exploiting the unique excitonic effect in dislocation and strain-free nanowires disclosed herein. Although it is known that excitonic devices can exhibit significantly enhanced efficiency compared to conventional LEDs due to the strong Coulombic interaction between electrons and holes, the realization of such devices has remained elusive in conventional quantum well LEDs, due to the large strain distribution and strong polarization field, which spatially separates the electrons and holes and weakens excitonic effect. As disclosed herein, defect and strain-free crystals in excitonic micro-LEDs can be grown, avoiding surface damage from processes that increase the Shockley-Read-Hall recombination. The reduced QCSE due to the strain-relaxed semi-polar facets in the InGaN/GaN active region, together with the strong quantum-confinement with the presence of indium-rich clusters, enhances the electron-hole wavefunction overlap and thereby enhances the exciton binding energy of submicron-scale nanowire LEDs as disclosed herein (e.g., with a diameter of less than 200 nm, a diameter of less than 150 nm, or a diameter as small as 100 nm).

Accordingly, micro-LEDs with emission across the entire visible spectrum can be grown, with efficiencies approaching or better than commercial broad area LEDs. Significantly, this disclosure offers a new landscape for the design and development of a broad range of devices to overcome the efficiency bottleneck of nanoscale optoelectronics.

In summary, as disclosed herein, several critical factors for achieving high-efficiency excitonic LEDs, including the epitaxy of small-size (submicron-scale) nanostructures to achieve strain relaxation, the utilization of semi-polar planes in the active region to reduce quantum-Confined Stark effect, and the formation of nanoscale quantum-confinement to enhance electron-hole wavefunction overlap, are identified.

In embodiments, N-polar GaN nanowires generally exhibit a flat top surface morphology, which makes the disclosed nanostructures well-suited for the fabrication of high efficiency devices.

As described herein, the EL spectrum is relatively broad, due to variations in the indium composition of the quantum disks.

As disclosed herein, the regions close to the nanowire surface show growth along facets (e.g., semi-polar planes). This effect gets noticeably stronger as the diameter of the nanowires decreases. There is significant growth of the quantum disks along the facets near the surface, particularly for smaller diameter nanowires. Larger nanowire diameters show reduced faceting. Nanowires that have a larger diameter and smaller spacing between the nanowires have a lower effective Ga adatom flux at the growth front due to the shadowing effect from nearby nanowires. The significantly reduced polarization field along with the facets (semi-polar planes) in small diameter nanowires suppress the QCSE, thereby dramatically enhancing the excitonic binding energy for quantum disks formed on these semi-polar planes.

As disclosed herein, the epitaxy of smaller diameter nanostructures achieves more efficient strain relaxation.

Stronger charge carrier (electrons and holes) confinement in the quantum disks (specifically, within the indium-doped layers in the quantum disks), together with the significantly reduced strain distribution and piezoelectric polarization field, greatly enhance the electron-hole wavefunction overlap, and thereby enhance the exciton binding energy. Furthermore, this effect depends strongly on the diameter of the nanostructures, with more efficient strain relaxation in nanowires having smaller diameters.

As disclosed herein, the current density at similar voltages is lower for devices with smaller diameter nanowires, likely due to the presence of larger densities of defects for nanowires with larger diameters. This also results in devices with larger diameter nanowires starting to show optical emission at higher current densities relative to devices with smaller diameter nanowires.

As disclosed herein, the EQE of devices with smaller diameter nanowires shows a much sharper increase in efficiency at low injection currents relative to devices with larger diameter nanowires.

FIGS. 6(a), 6(b), 6(c), 6(d), 6(e), and 6(f) illustrate a process 600 for fabricating devices in embodiments according to the present invention.

In embodiments, to prepare the substrate for SAE, an N-polar GaN-on-sapphire template is first coated with a thin 10 nm thick mask layer of titanium (Ti) that is deposited using electron beam evaporation. Next, electron beam lithography is used to define arrays of openings in the Ti mask, for the growth of the nanowires. Each array has openings with fixed size and spacing, and these parameters are varied in the different arrays. The Ti in the exposed regions is carefully etched open using reactive ion etching (RIE). The etched substrate is cleaned in solvents to remove electron beam resist residue and then loaded into a molecular beam epitaxial (MBE) system.

In embodiments, the nanowires are grown in a Veeco GEN930 plasma-assisted MBE system. Prior to nanowire growth, the substrate is exposed to nitrogen plasma to ensure complete nitridation of the Ti mask layer. The growth is initiated with a Si-doped n-GaN layer. After the growth of this segment, the substrate temperature is reduced for the growth of the quantum disk active region. To obtain green emission from the quantum disks, an In/Ga flux ratio of approximately 0.6 is used, as measured using a beam flux monitor (BFM). After the growth of the active region, the growth temperature is further increased for growing the upper (e.g., Mg-doped) p-GaN layer.

In an embodiment, the nanowire array 602 is first coated with approximately 65 nm of aluminum oxide (Al₂O₃) deposited using atomic layer deposition (ALD) (FIGS. 6(a) and 6(b)).

The Al₂O₃ layer 604 is then etched back using RIE to reveal the top of the nanowires 606 (FIGS. 6(b) and 6(c)).

Following the etch-back, another insulating layer of approximately 500 nm of silicon dioxide (SiO₂) is deposited through plasma-enhanced chemical vapor deposition (PECVD) (FIGS. 6(c) and 6(d)).

Projection lithography is used to define sub-micron vias in the nanowire arrays, and the SiO₂ within these vias is etched using RIE to expose the nanowires 606 (FIG. 6(e)).

Next, metal is deposited for the p and n electrodes (contacts) 608 and 610 (FIG. 6(f)). In an embodiment, a Ti/gold (Au) (20 nm and 100 nm thicknesses, respectively) stack is used as the n-contact, while a Ni/Au/indium tin oxide (ITO) (five nm, five nm, and 200 nm thicknesses, respectively) stack is used as the p-contact. The electrodes 608 and 610 are annealed using rapid thermal annealing in a forming gas ambient at 450° C. for one minute.

In embodiments, the fabricated devices are designed for backside emission of light, so a reflective silver (Ag)/Ti/Al/nickel (Ni)/Au (100 nm, 20 nm, 100 nm, 20 nm, and 50 nm thicknesses, respectively) metal stack is deposited over the device to maximize light extraction from the bottom surface. Finally, the backside sapphire substrate is thinned down so that the sapphire thickness is approximately 100 micrometers.

Although the subject matter has been described in language specific to structural features and/or methodological acts, it is to be understood that the subject matter defined in the present disclosure is not necessarily limited to the specific features or acts described above. Rather, the specific features and acts described above are disclosed as example forms of implementing the present disclosure.

Embodiments according to the present disclosure are thus described. While the present invention has been described in particular embodiments, the invention should not be construed as limited by such embodiments, but rather construed according to the following claims.

What is claimed is:

1. An excitonic device, comprising:
a substrate;
a plurality of nanowires coupled to the substrate, wherein electrons and holes are spatially confined within an active region of each nanowire of the plurality of nanowires; and
electrodes coupled to the plurality of nanowires, wherein the plurality of nanowires are operable for electroluminescent emission originating from excitons comprising bound states of electrons and holes in the active region of said each nanowire.

2. The excitonic device of claim 1, wherein the active region of said each nanowire comprises layers of semiconductor material on semi-polar planes of said each nanowire.

3. The excitonic device of claim 1, wherein the active region of said each nanowire is non-uniformly doped with indium, comprising indium-rich clusters, and wherein the indium-rich clusters in the active region of said each nanowire enhance the binding energies of the excitons.

4. The excitonic device of claim 1, wherein the active region of said each nanowire comprises an indium-gallium-nitride (InGaN) layer having a central region and edges around the central region, wherein the central region of the InGaN layer in the active region is disposed on a c-plane within the active region and the edges of the InGaN layer are disposed on semi-polar planes within the active region that intersect the c-plane.

5. The excitonic device of claim 1, wherein the substrate comprises an N-polar substrate, and wherein the plurality of nanowires comprises gallium nitride (GaN)-based nanowires.

6. The excitonic device of claim 5, wherein the distal surface of each nanowire of the GaN-based nanowires has a central area that is flat with chamfered edges.

7. The excitonic device of claim 5, wherein the active region of said each nanowire of the plurality of nanowires comprises a plurality of layers of gallium nitride (GaN) and a plurality of layers of indium gallium nitride (InGaN), wherein each InGaN layer of the plurality of InGaN layers has a concentration of indium that is higher at the edges of said each nanowire relative to a central region of said each nanowire.

8. The excitonic device of claim 1, with an external quantum efficiency (EQE) of at least 20%.

9. The excitonic device of claim 8, wherein the EQE of at least 20% is at an injection current greater than 0.1 amperes per square centimeter (A/cm²).

10. The excitonic device of claim 1, wherein the electroluminescent emission includes an emission peak at a wavelength in the green spectrum.

11. The excitonic device of claim 1, having a wall-plug efficiency of greater than 15%.

12. A nanowire, comprising:
a submicron-scale heterostructure, comprising:
a first semiconductor region;
a second semiconductor region; and
an active region comprising a plurality of quantum disks between and coupled to the first semiconductor region and the second semiconductor region, wherein the plurality of quantum disks comprises indium-doped quantum disks, each indium-doped quantum disk of the indium-doped quantum disks having a central region and edges around the central region, wherein the central region of said each indium-doped quantum disk is disposed on a c-plane within the active region and the edges of said each indium-doped quantum disk are disposed on semi-polar planes within the active region that intersect the c-plane, and wherein electrons and holes are spatially confined within the active region.

13. The nanowire of claim 12, wherein the indium-doped quantum disks are non-uniformly doped with indium, comprising indium-rich clusters in the indium-doped quantum disks, and wherein the indium-rich clusters in the active region enhance the binding energies of the excitons.

14. The nanowire of claim 12, wherein the first semiconductor region comprises n-doped gallium nitride (n-GaN), wherein the second semiconductor region comprises p-doped gallium nitride (p-GaN), wherein the plurality of quantum disks comprises a plurality of layers of gallium nitride (GaN) and a plurality of layers of indium gallium nitride (InGaN), and wherein each InGaN layer of the plurality of InGaN layers has a concentration of indium that is higher at the edges of the nanowire relative to the central region of the nanowire.

15. The nanowire of claim 12, wherein the distal surface of the nanowire comprises a central area that is flat with chamfered edges.

16. The nanowire of claim 12, with an external quantum efficiency (EQE) of at least 20% at an injection current greater than 0.1 amperes per square centimeter (A/cm²).

17. The nanowire of claim 12, wherein the excitonic electroluminescent emission includes an emission peak at a wavelength in the green spectrum.

18. The nanowire of claim 12, having a wall-plug efficiency greater than 15%.

19. The nanowire of claim 12, wherein the nanowire has a diameter selected from the group consisting of: a diameter of less than 200 nanometers (nm), a diameter of less than 150 nm, and a diameter of 100 nm.

20. An excitonic device, comprising:
a substrate; and
an excitonic light-emitting diode (LED) coupled to the substrate and comprising a nanowire array comprising a plurality of submicron-scale nanowires, wherein each submicron-scale nanowire of the plurality of submicron-scale nanowires is operable for electroluminescent emission originating from bound states of excitons comprising electrons and holes spatially confined in an active region of said each submicron-scale nanowire;
wherein the active region of said each submicron-scale nanowire comprises a plurality of quantum disks, wherein the plurality of quantum disks comprises a plurality of indium-doped quantum disks, each indium-doped quantum disk of the plurality of indium-doped quantum disks having a central region and edges around the central region, and wherein the central region of said each indium-doped quantum disk is disposed on a c-plane within the active region and the edges of said each indium-doped quantum disk are disposed on semi-polar planes within the active region that intersect the c-plane.

21. The excitonic device of claim 20, wherein the active region of said each submicron-scale nanowire is non-uniformly doped with indium, comprising indium-rich clusters in the active region, and wherein the indium-rich clusters in the active region of said each submicron-scale nanowire enhances the binding energies of the excitons.

22. The excitonic device of claim 20, wherein the substrate comprises an N-polar substrate, and wherein the plurality of submicron-scale nanowires comprises a plurality of submicron-scale gallium nitride (GaN)-based nanowires disposed on the substrate.

23. The excitonic device of claim 20, wherein the distal surface of said each submicron-scale nanowire comprises a central area that is flat with chamfered edges.

24. The excitonic device of claim 20, wherein said each submicron-scale nanowire comprises:
a first semiconductor region comprising n-doped gallium nitride (n-GaN); and
a second semiconductor region comprising p-doped gallium nitride (p-GaN);
wherein the plurality of quantum disks is disposed between the first semiconductor region and the second semiconductor region, wherein the plurality of quantum disks also comprises a plurality of layers of gallium nitride (GaN), wherein the plurality of indium-doped quantum disks comprises a plurality of layers of indium gallium nitride (InGaN), and wherein each InGaN layer of the plurality of InGaN layers has a concentration of indium that is higher at the edges of said each nanowire relative to the central region of said each nanowire.

25. The excitonic device of claim 20, having an external quantum efficiency (EQE) of at least 20% at an injection current greater than 0.1 amperes per square centimeter (A/cm²).

26. The excitonic device of claim 20, wherein the electroluminescent emission includes an emission peak at a wavelength in the green spectrum.

27. The excitonic device of claim 20, having a wall-plug efficiency of greater than 15%.

28. An excitonic device, comprising:
a substrate;
an inorganic crystalline semiconductor coupled to the substrate, wherein electrons and holes are spatially confined within an active region of the inorganic crystalline semiconductor; and
electrodes coupled to the inorganic crystalline semiconductor, wherein the inorganic crystalline semiconductor is operable for electroluminescent emission originating from excitons comprising bound states of electrons and holes in the active region of the inorganic crystalline semiconductor; and
wherein the inorganic crystalline semiconductor material comprises indium-gallium nitride.

29. A semiconductor device, comprising indium-gallium-nitride, wherein the exciton binding energy of the electrons and holes within the semiconductor is greater than 0.025 electron-volts, such that the excitons are bound at room temperature.
